(19) United States
(12) Patent Application Publication
(10) Pub. No.: US 2025/0261300 A1
(43) Pub. Date: Aug. 14, 2025

(54) METHODS AND APPARATUS TO COOL HOTSPOTS IN INTEGRATED CIRCUIT PACKAGES

(71) Applicant: Intel Corporation, Santa Clara, CA (US)

(72) Inventors: Harald Gossner, Riemerling (DE); Luis Alberto Couto Da Silva Salgado De Abreu, Munich (DE); Wolfgang Molzer, Ottobrunn (DE); Johannes Xaver Rauh, Kirchseeon (DE); Stefan Rolf, Düsseldorf (DE); Thomas Helmut Wagner, Regelsbach (DE)

(73) Assignee: Intel Corporation, Santa Clara, CA (US)

(21) Appl. No.: 19/076,554

(22) Filed: Mar. 11, 2025

(51) Int. Cl. H05K 1/02; H05K 1/09; H10N 10/10

(52) U.S. Cl. CPC H05K 1/021; H05K 1/0272; H05K 1/092; H10N 10/10

(57) ABSTRACT

Systems, apparatus, articles of manufacture, and methods to cool hotspots in integrated circuit packages are disclosed. An example apparatus includes a heat generating component associated with a first location in a semiconductor die and a heatsink assembly at a second location in the semiconductor die. The first location is spaced apart from the second location. The example apparatus including a thermally conductive material to thermally couple the heat generating component and the heatsink assembly.

### BACKGROUND

Electronic components, such as microprocessors and integrated circuit packages, generally produce heat during operation. Excessive heat may degrade the performance, reliability, and/or life expectancy of such electronic components and may even cause component failure. Accordingly, in many instances, cooling systems are implemented to dissipate heat from such electronic components to maintain the operational temperature of such components within a suitable range.

### BRIEF DESCRIPTION OF THE DRAWINGS

FIG. 1 illustrates an example integrated circuit (IC) package constructed in accordance with teachings disclosed herein.

FIG. 2 is a top view of the example first semiconductor die of FIG. 1.

FIG. 3 is a close-up perspective view of an example ring surrounding an associated hotspot in the example first semiconductor die of FIGS. 1 and/or 2.

FIG. 4 is a close-up perspective view of an example cage surrounding an associated hotspot in the example first semiconductor die of FIGS. 1 and/or 2.

FIG. 5 is a close-up perspective view of another example cage surrounding an associated hotspot in the example first semiconductor die of FIGS. 1 and/or 2.

FIG. 6 illustrates an example implementation of the example heatsink assembly of FIGS. 1 and/or 2.

FIG. 7 is a perspective view of an example ring surrounding the example channel shown in FIG. 6.

FIG. 8 is a cross-sectional view of a wall of an example cage associated with the example ring of FIG. 7.

FIG. 9 illustrates another example implementation of the example heatsink assembly of FIGS. 1 and/or 2.

FIG. 10 illustrates a stack of semiconductor dies including a plurality of fluid coolant channels extending therethrough in accordance with teachings disclosed herein.

FIG. 11 illustrates another example implementation of the example heatsink assembly of FIGS. 1 and/or 2.

FIG. 12 illustrates another example implementation of the example heatsink assembly of FIGS. 1 and/or 2.

FIG. 13 illustrates another example implementation of the example heatsink assembly of FIGS. 1 and/or 2.

FIG. 14 illustrates another example implementation of the example heatsink assembly of FIGS. 1 and/or 2.

FIG. 15 illustrates another example IC package constructed in accordance with teachings disclosed herein.

FIG. 16 illustrates an example arrangement of thermally conductive material to facilitate heat transfer from a hotspot to a heatsink area corresponding to any given type of heatsink assembly disclosed herein.

FIG. 17 is a top view of a wafer including dies that may be included in an IC package constructed in accordance with teachings disclosed herein.

FIG. 18 is a cross-sectional side view of an IC device that may be included in an IC package constructed in accordance with teachings disclosed herein.

FIG. 19 is a cross-sectional side view of an IC device assembly that may include an IC package constructed in accordance with teachings disclosed herein.

FIG. 20 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

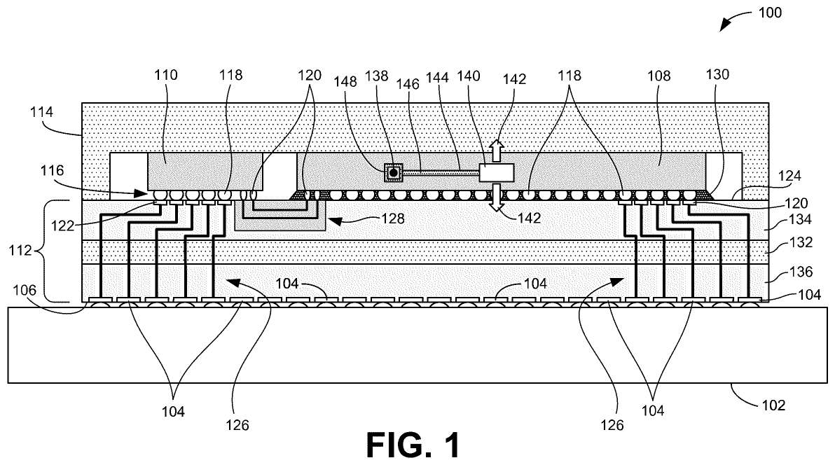

FIG. 1 illustrates an example integrated circuit (IC) package 100 constructed in accordance with teachings disclosed herein. In the illustrated example, the IC package 100 is electrically coupled to an underlying substrate 102 via an array of contacts 104 on a package mounting surface 106 (e.g., a bottom surface, an external surface) of the package. In some examples, the substrate 102 can be implemented by a printed circuit board (PCB) or a package substrate (e.g., the IC package 100 is part of another larger package). In the illustrated example, the contacts 104 are represented as pads or lands. However, in some examples, the IC package 100 may include balls, pins, and/or any other type(s) of contact(s), in addition to or instead of the pads or lands shown to enable the electrical coupling of the IC package 100 to the substrate 102. In this example, the package 100 includes two semiconductor dies 108, 110 (e.g., silicon dies), sometimes also referred to as chips or chiplets, that are mounted to a package substrate 112 and enclosed by a package lid 114 (e.g., a mold compound, an integrated heat spreader (IHS)). Thus, the package substrate 112 is an example means for supporting a semiconductor die. In some examples, the package lid 114 is omitted, thereby leaving the semiconductor dies 108, 110 exposed or bare.

While the example IC package 100 of FIG. 1 includes two dies 108, 110, in other examples, the IC package 100 may have only one die or more than two dies. In some examples, one of the dies 108, 110 (or a separate die) is embedded in the package substrate 112. The dies 108, 110 can provide any suitable type of functionality (e.g., data processing, memory storage, etc.). In some examples, one or both of the dies 108, 110 are implemented by a die package including multiple dies arranged in a stacked formation. For example, the die 110 can include a stack of Dynamic Random Access Memory (DRAM) dies arranged on top of a memory controller die to form a memory die stack.

As shown in the illustrated example, each of the dies 108, 110 is electrically and mechanically coupled to the package substrate 112 via corresponding arrays of interconnects 116. In FIG. 1, the interconnects are shown as bumps. In some examples, the interconnects 116 can include solder joints, micro bumps, combinations of metallic (e.g., copper) pillars and solder, etc. In other examples, the interconnects 116 may include directly bonded or “hybrid bonded” metallic interconnects. In other examples, the interconnects 116 may be any other type of electrical connection in addition to or instead of the bumps shown (e.g., balls, pins, pads, pillars, wire bonding, etc.). The electrical connections between the dies 108, 110 and the package substrate 112 (e.g., the interconnects 116) are sometimes referred to as first level interconnects. By contrast, the electrical connections between the IC package 100 and the substrate 102 (e.g., the contacts 104) are sometimes referred to as second level interconnects. In some examples, one or both of the dies 108, 110 may be stacked on top of one or more other dies and/or an interposer. In such examples, the dies 108, 110 are coupled to the underlying die and/or interposer through a first set of first level interconnects and the underlying die and/or interposer may be connected to the package substrate 112 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 116 of the first level interconnects include two different types of bumps corresponding to core bumps 118 and bridge bumps 120. As used herein, the core bumps 118 are bumps on the dies 108, 110 through which electrical signals pass between the dies 108, 110 and components external to the IC package 100. More particularly, as shown in the illustrated example, when the dies 108, 110 are mounted to the package substrate 112, the core bumps 118 are physically connected and electrically coupled to contact pads 122 on a die mounting surface 124 (e.g., an upper surface, a top surface, etc.) of the package substrate 112. The contact pads 122 on the die mounting surface 124 of the package substrate 112 are electrically coupled to the contacts 104 on the package mounting surface 106 (e.g., the bottom, external surface) of the package substrate 112 (e.g., a surface opposite the die mounting surface 124) via internal interconnects 126 within the package substrate 112. As a result, there is a continuous electrical signal path between the core bumps 118 of the dies 108, 110 and the contacts 104 mounted to the substrate 102 that pass through the contact pads 122 and the interconnects 126 provided therebetween. As shown, the package mounting surface 106 and the die mounting surface 124 define opposing outer surfaces of the package substrate 112. While both surfaces are outer surfaces of the package substrate, the die mounting surface 124 is sometimes referred to herein as an internal or inner surface relative to the overall IC package 100. By contrast, in this example, the package mounting surface 106 is an outer or exterior surface of the IC package 100.

As used herein, the bridge bumps 120 are bumps on the dies 108, 110 through which electrical signals pass between different ones of the dies 108, 110 within the IC package 100. Thus, as shown in the illustrated example, the bridge bumps 120 of the first die 108 are electrically coupled to the bridge bumps 120 of the second die 110 via an interconnect bridge 128 (e.g., a silicon-based interconnect bridge, an interconnect die, an embedded interconnect bridge (EMIB)) embedded in the package substrate 112. As represented in FIG. 1, core bumps 118 are typically larger than bridge bumps 120. In some examples, the interconnect bridge 128 and the associated bridge bumps 120 are omitted.

In some examples, an underfill material 130 is disposed between the dies 108, 110 and the package substrate 112 around and/or between the first level interconnects 116 (e.g., around and/or between the core bumps 118 and/or the bridge bumps 120). In the illustrated example, only the first die 108 is associated with the underfill material 130. However, in other examples, both dies 108, 110 are associated with the underfill material 130. In other examples, the underfill material 130 is omitted. In some examples, the mold compound used for the package lid 114 is used as an underfill material that surrounds the first level interconnects 116.

In some examples, the IC package 100 includes additional passive components, such as surface-mount resistors, capacitors, and/or inductors disposed on the package mounting surface 106 of the package substrate 112 and/or the die mounting surface 124 of the package substrate 112.

In FIG. 1, the substrate 112 of the example IC package 100 includes a core 132 between two separate build-up layers or regions 134, 136 (e.g., a first build-up region 134 and a second build-up region 136). In some examples, the core 132 is a glass core (e.g., a glass substrate, amorphous solid glass layer etc.). That is, in some examples, the core 132 is a layer of glass that does not include an organic adhesive or an organic material. In some examples, the core 132 includes silicon, a dielectric material and/or any other material(s). In other examples, the core 132 includes an organic material (e.g., epoxy-based prepreg).

The first and second build-up regions 134, 136 are represented in FIG. 1 as masses/blocks with the internal interconnects 126 extending in straight lines through the build-up regions 134, 136 (and the core 132). However, FIG. 1 has been simplified for the sake of clarity and purposes of explanation. In practice, the interconnects are not necessarily straight. More particularly, in some examples, the build-up regions 134, 136 are defined by alternating layers of dielectric material and layers of electrically conductive material (e.g., a metal such as copper). The conductive (metal) layers serve as the basis for the internal interconnects 126 represented, in a simplified form, by straight lines as shown in FIG. 1. In some examples, the metal layers are patterned to define electrical routing or conductive traces that are electrically coupled between different metal layers by conductive (e.g., metal) vias extending through intervening dielectric layers. Further, the electrical routing or traces on either side of the core 132 may be electrically coupled by plated through-holes (e.g., copper plated vias) extending through the core 132.

In the illustrated example of FIG. 1, the first semiconductor die 108 includes a hotspot 138 (e.g., a heat generating component). As used herein, a hotspot is a location or region in a semiconductor die that produces more heat than other areas of the die. That is, in some examples, a hotspot is defined based on a temperature differential between the location of the hotspot and other locations and not necessarily the actual measured temperature of the hotspot or the other locations. Thus, in some examples, an entire semiconductor die may be relatively cool, but a certain location is at a relatively higher temperature than other locations so as to qualify as a hotspot. In some examples, a location is identified as a hotspot only when a temperature differential between the location and other locations satisfies (e.g., exceeds) a differential temperature threshold. In some examples, as used herein, a hotspot refers to a location in a semiconductor die with a temperature that satisfies (e.g., exceeds) a temperature threshold regardless of the temperature of other locations on the package. In some examples, as used herein, a hotspot refers to a location in a semiconductor die with a temperature that both satisfies (e.g., exceeds) a temperature threshold and that results in a temperature differential relative to other locations on the package that satisfies (e.g., exceeds) a temperature differential threshold. Thus, a hotspot may be defined in terms of absolute (e.g., measured) temperatures at specific locations of a semiconductor die and/or in terms of temperature gradients (e.g., temperature differentials) across the semiconductor die. The foregoing explanation of a hotspot assumes that the hotspot is not being cooled in a way that draws away heat in a manner that prevents the hotspot reaching a certain threshold and/or producing a certain temperature threshold. In other words, a hotspot is a location or region in a semiconductor die that has a higher thermal output than other areas of the die when in operation to give rise to high temperatures and/or temperature differentials if not mitigated by a cooling system. The source of heat produced by a hotspot corresponds to active components (e.g., transistors) within the semiconductor die. However, as defined herein, hotspots are not limited to the location of such transistors, but can extend into the metal interconnects to which the heat producing transistors are electrically coupled. While examples disclosed herein are described with reference to a hotspot 138, examples disclosed herein can be applied in connection with any region or area within a semiconductor die that produces heat regardless of whether it produces more heat than other areas or not. That is, any heat generating component and/or region of a semiconductor die could be implemented in place of the hotspot 138 shown in FIG. 1 regardless of whether or not the heat generating component and/or region meets the definition of a hotspot.

Insufficient heat dissipation in densely packed integrated circuits can lead to reliability issues, reduced performance, and/or device failure based on electromigration, active loss, and/or leakage currents. Such concerns become of greater concern when there are localized hotspots, such as the hotspot 138 represented in FIG. 1. In the past, the bulk portion of semiconductor material (e.g., the silicon wafer) on which transistors are fabricated could absorb and/or spread out at least some of the heat produced by such wafers. However, as transistors have gotten smaller and positioned more densely together, the bulk layer of semiconductor material in a die has become insufficient for this purpose. Moreover, in some technologies (such as for gate-all-around (GAA) transistors and complementary field effect transistors (CFET)), the bulk portion of the semiconductor material is thinned and/or removed so that it is not available to provide a heat spreading functionality.

One known approach to dissipating heat from a localized hotspot includes the placement of a heatsink as close as possible to the hotspot. However, such heatsinks are usually placed on or adjacent to outer surfaces of the semiconductor die and/or associated package housing (e.g., the integrated heat spreader 114). As a result, such heatsinks have relatively little impact on the thermal gradient within a semiconductor die. This can become an even greater problem for a 3D stack of semiconductor dies. One solution is to include thermally conductive towers (fabricated from metal vias successively connected different metal layers in the semiconductor die) to facilitate the transfer of heat from the hotspot to the exterior of the semiconductor die and/or associated package housing. However, such towers need to be placed as close as possible to the hotspot, which can place limitations on circuit design due to the space used up by the conductive towers and their location directly aligned with hotspots. Another known approach to mitigate against localized hotspots is the implementation of performance throttling to avoid excessive local temperature arising from transistor self-heating. While this approach can reduce the overall amount of heat produced, throttling reduces the performance of an associated integrated circuit and may underutilize circuitry that is not associated with the hotspot(s).

Examples disclosed herein address the above concerns by implementing cooling systems directly within the semiconductor die. Such cooling systems include a heatsink assembly 140 (e.g., mini cooler) spaced apart (e.g., laterally spaced apart or offset) from the hotpot 138. As used herein, a heatsink assembly (also referred to herein simply as a heatsink for short) is expressly defined to include any type of material, arrangement of materials, device, and/or assembly that is capable of absorbing and/or drawing away heat from another source (e.g., the hotspot 138) to facilitate the dissipation of heat from the other source. In some examples, the heatsink assembly 140 is constructed to then pass on or transfer the heat away from the semiconductor die 108 into some external component (e.g., an adjacent (e.g., stacked) semiconductor die, an interposer, a package substrate (e.g., the package substrate 112), an integrated heat spreader (e.g., the package lid 114), or some other heatsink external to the IC package 100). In some examples, such heat transfer can be transmitted in multiple directions as represented by the arrows 142. In some examples, heat collected by the heatsink assembly 140 is dissipated substantially in one direction. In some examples, heat collected by the heatsink assembly 140 is stored temporarily and then dissipated back into the semiconductor die 108 at a later point in time after the temperature of the hotspot 138 has subsided.

Although the heatsink assembly 140 is described as being spaced apart from the hotspot 138, the heatsink assembly 140 can be at any suitable distance from the hotspot 138 including right next to the hotspot 138. Indeed, the cooling efficiency of the heatsink assembly 140 increases as the distance between the heatsink assembly 140 and the hotspot 138 decreases. However, unlike known approaches that require heatsinks to be directly aligned with and/or as close as possible, the example heatsink assembly 140 can be positioned some distance away from the hotspot 138 and still provide sufficient cooling capacity to mitigate against concerns of overheating. In some examples, the distance or lateral offset between the hotspot 138 and the heatsink assembly 140 is at least 1 micrometer (μm) but can be at much greater extents (e.g., at least 1.5 μm, at least 2 μm, at least 3 μm, at least 5 μm, at least 10 μm, at least 25 μm, etc.).

As shown in the illustrated example, the heatsink assembly 140 is able to draw heat away from the hotspot, despite being spaced apart, because the associated cooling system also includes thermally conductive material 144 (e.g., a thermal conductor) that extends between heatsink assembly 140 and the hotspot 138, thereby thermally coupling the two regions. In some examples, the thermally conductive material 144 includes a metal (e.g., copper) that is deposited within the semiconductor die 108 at the same time that the metal for internal interconnects within the die 108 are deposited. That is, in some examples, the metal used for the routing of interconnects is the same metal used for the thermally conductive material 144. In some examples, a material with greater thermal conductivity is used for the thermally conductive material 144 (e.g., graphene) as compared with the material used for the interconnects (e.g., copper). More particularly, copper has a thermal conductivity of approximately 400 watts per meter-Kelvin (W/mK). While this is significantly higher than the thermal conductivity of silicon (a common material for the bulk semiconductor substrate for a die), which is approximately 148 W/mK, it is significantly lower than the thermal conductivity of graphene, which can range between approximately 3000 W/mK and 5000 W/mK.

In the illustrated example, the thermally conductive material 144 is shown extending between the hotspot 138 and the heatsink assembly 140 in a single plane or single metal layer. However, in other examples, the thermally conductive material 144 can extend between the hotspot 138 and the heatsink assembly 140 in multiple different metal layers within the semiconductor die 108. In some examples, the thermally conductive material 144 in the different metal layers is thermally coupled to one another by metal vias extending therebetween. However, in other examples, such metal vias are omitted. Providing the thermally conductive material 144 between the hotspot 138 and the heatsink assembly 140 enables the heatsink assembly 140 to be positioned at any suitable location within semiconductor die 108, thereby providing for greater flexibility in the circuit design of the die 108.

More particularly, by modelling the heat flux associated with the thermally conductive material 144 and the heatsink at an early stage of the circuit design process, such cooling network components can be added as building block to the active circuitry during subsequent circuit design processes. In some examples, the heatsink assembly 140 and the connected heat transport network (e.g., the thermally conductive material 144) can be designed in after the electrical optimization of a 3D stack. Choosing the right dimensions for the cooling network components removes the limitations of excessive overheating. As a result, this removes the need for the throttling of an integrated circuit to avoid such overheating, thereby achieving better performance than past solutions that depend on throttling. Thus, little to no concern needs to be taken into account relating to circuit performance. Accordingly, the placement and/or dimensions of the heatsink assembly 140 and the associated thermally conductive material 144 can be made based on a thermal simulation after the optimum circuit solution and IP placement of an integrated circuit has been decided. This can significantly streamline the design process because no additional iterations of circuit improvements and/or modification of firmware to avoid overheating is needed.

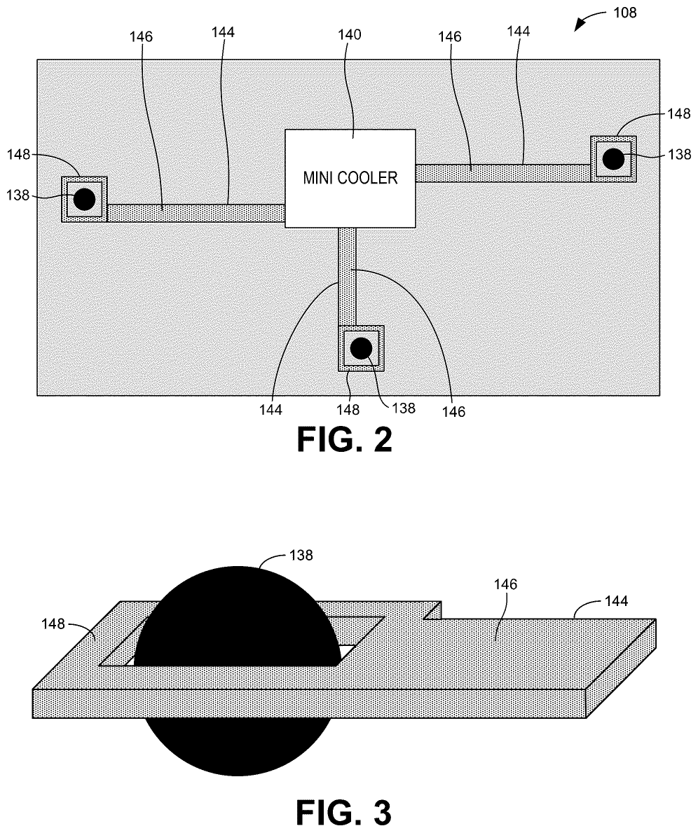

In some examples, positioning the heatsink assembly 140 a distance from the hotspot 138 enables the heatsink assembly 140 to be thermally coupled to another hotspot 138 at a different location. That is, although FIG. 1 shows only one hotspot 138, in some examples, the semiconductor die 108 can include multiple hotspots 138. In some such examples, heat produced at these different hotspots 138 is dissipated by the same heatsink assembly 140 to which the different hotspots 138 are thermally coupled. In this manner, a single heatsink assembly 140 can serve to dissipate heat from multiple disparately located hotspots 138, thereby saving space within the semiconductor die 108 relative to a design in which a separate heatsink assembly 140 is implemented for each hotspot 138. This is illustrated in FIG. 2, which shows a top view of the first example semiconductor die of FIG. 1 with the single heatsink assembly 140 thermally coupled to each of three different hotspots 138 by respective lines, arms, or elongate plates 146 of the thermally conductive material 144. In other examples, the first semiconductor die 108 includes more than one heatsink assembly 140. In some examples, the number of heatsink assemblies 140 is equal to the number of hotspots 138. In some examples, the number of heatsink assemblies 140 exceeds the number of hotspots 138. In some examples, a single hotspot 138 is thermally coupled to multiple heatsink assemblies 140 to increase the dissipation of heat from the hotspot 138.

Although each of the elongate plates 146 associated with the thermally conductive material 144 are shown in FIGS. 1 and 2 as extending in straight lines, the elongate plates 146 can curve, bend, and/or otherwise follow any suitable path between the hotspot 138 and the heatsink assembly 140 that are to be thermally coupled by the elongate plates 146. In some examples, the elongate plates 146 are dimensioned similarly to the traces for interconnects (e.g., electrical routing) within the semiconductor die 108. In other examples, the elongate plates 146 are larger than traces for greater thermal conduction. More particularly, in some examples, the elongate plates 146 have a similar thickness to traces (defined by the thickness of the corresponding metal layer), but the widths of the elongate plates 146 can be larger than the widths of traces. In some examples, the elongate plates 146 are integrated into (e.g., a part of) the power distribution network in the semiconductor die 108.

In some examples, as shown in both FIGS. 1 and 2, the thermally conductive material 144 includes and/or defines a ring 148 (e.g., a thermal guard ring, a heat conducting ring, a heat conducting cage, an end plate, etc.) at an end of the elongate plates 146 that is proximate the hotspots 138 and distal to the heatsink assembly 140. In some examples, the rings 148 at least partially surround a corresponding hotspot 138. FIG. 3 is a close-up perspective view of one of the rings 148 surrounding an associated hotspot 138. In the illustrated examples, the hotspots 138 are represented by dark spots. However, as explained above, a hotspot is any location that is associated with the generation of an excessive amount of heat (relative to other areas of the semiconductor die 108) and typically corresponds to one or more transistors and the associated metal interconnects electrically coupled to such transistors. Notably, it is the transistors themselves that generate the heat, but such heat can be conducted along the associated metal interconnects thereby expanding the location of the hotspot 138. There may also be some spread of the heat through and into the dielectric material around and between the transistors and the associated metal interconnects but this is relatively minimal relative to heat conduction along the interconnects based on the difference in thermal conductivity between the metal (e.g., copper) and the dielectric material (e.g., silicon dioxide). Specifically, whereas copper has a thermal conductivity of approximately 400 W/mK, silicon dioxide has a thermal conductivity of less than 2 W/mK.

In some examples, while the ring 148 surrounds the hotspot 138, the ring 148 remains electrically isolated from the hotspot 138 (e.g., electrically isolated from the transistors and associated interconnects electrically coupled to the transistors). In some examples, the ring 148 is in direct metallic contact with the circuitry associated with the hotspot 138 (e.g., if there is no electrical constraint such as for VCC rails). In the illustrated example, the ring 148 completely surrounds (e.g., extends a full circumference) around the hotspot 138. However, in other examples, the ring 148 only partially surrounds (e.g., forms a C-shape or U-shape around, positioned to flank opposing sides of) corresponding hotspots 138. In some examples, the ring 148 is open in at least one location along its perimeter to enable electrical routing to connect to pass through while maintaining electrical isolation between the routing and the ring 148. Further, although the ring 148 is shown as having a rectangular shape in the illustrated example, the ring 148 can be any other suitable shape (e.g., circular, oval, triangular, etc.).

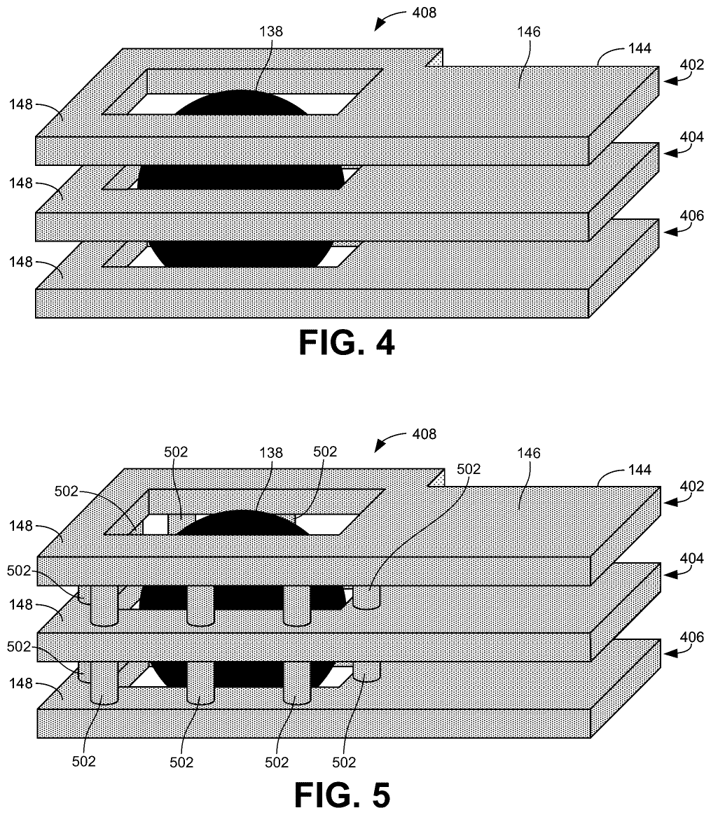

In some examples, the ring 148 is defined by a path of metal that resides within a given plane as the metal (partially or completely) surrounds the hotspot 138. In some examples, the plane containing the ring 148 corresponds to a plane defined by a given metal layer in the semiconductor die 108 (as shown in FIG. 2). That is, the ring 148 is in the same metal layer as the elongate length of the thermally conductive material 144 extending between the hotspot 138 and the heatsink assembly 140. In some examples, the plane extends transverse (e.g., perpendicular) to a given metal layer (as shown in FIG. 1). In some such examples, portions of the ring 148 extending transverse to a given metal layer are defined by metal vias. In some examples, the ring 148 is one of multiple substantially parallel rings 148 in different metal layers 402, 404, 406 to define a three-dimensional cage 408 as shown in the illustrated example of FIG. 4. In some examples, the metal layers are adjacent to one another (e.g., with only one dielectric layer situated therebetween). In other examples, the metal layers containing the rings 148 are separated by one or more other metal layers (along with associated dielectric layers between each adjacent pair of metal layers). In some examples, the separate metal rings 148 are thermally coupled by one or more metal vias 502 extending therebetween as shown in the illustrated example of FIG. 5. In some examples, similar metal vias extend between the different elongate plates 146 associated with the different rings 148. In some examples, vias extend between the different elongate plates 146 while the metal vias 502 between the rings 148 are omitted.

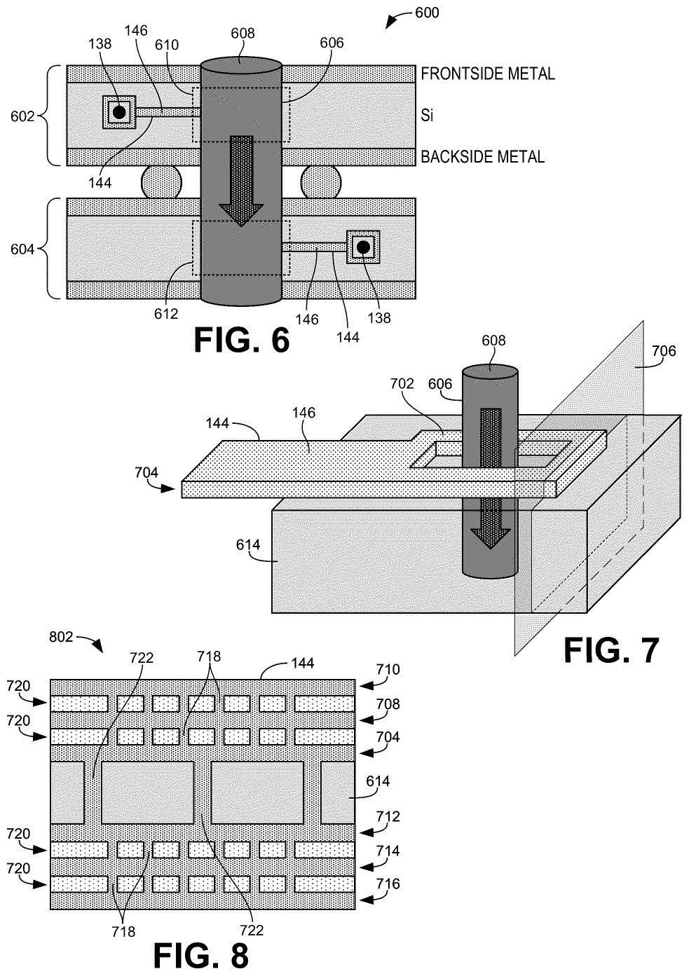

The ring(s) 148 and/or the associated cage 408 surround a corresponding hotspot 138 to collect or draw heat away from the hotspot 138 as thermal energy is conducted along the associated elongate plates 146 of the thermally conductive material 144 towards the heatsink assembly 140. The example heatsink assembly 140 shown in FIGS. 1 and 2 can be implemented in many different ways. For instance, in some examples, the heatsink assembly 140 is based on an active cooling method that relies on the flow of a fluid coolant and/or an electrically activated Peltier device. In some examples, the heatsink assembly 140 includes a mass or block of highly thermally conductive material such as carbon nanotubes (e.g., with a thermal conductivity of at least 2800 W/mK and as high as approximately 6000 W/mK). In some examples, the heatsink assembly 140 locally stores collected heat for a temporary period of time (e.g., until the hotspot 138 cools down from peak performance). In some such examples, the heatsink assembly 140 is implemented with a phase change material that undergoes a phase change when heated and then reverses the change later on when the heat is released. Different example implementations of the heatsink assembly 140 of FIGS. 1 and 2 are described further below in connection with FIGS. 6-15.

The heatsink assembly 140 and the associated thermally conductive material 144 of FIGS. 1 and 2 are shown and described as implemented within the first semiconductor die 108. However, in some examples, a similar heatsink assembly 140 and associated thermally conductive material 144 can be additionally or alternatively implemented in the second semiconductor die 110 of FIG. 1.

FIG. 6 illustrates a 3D stack 600 of multiple semiconductor dies (e.g., a first semiconductor die 602 and a second semiconductor die 604) with an example channel 606 (e.g., through silicon via (TSV), pipe, etc.) extending through the stack 600. As shown in the illustrated example, the channel 606 extends transversely through the stack 600 of semiconductor dies 602, 604 to enable the passage or flow of a fluid coolant 608 through the dies 602, 604. While the stack 600 is shown to include two semiconductor dies 602, 604, in some examples, the stack 600 includes more than two dies. Additionally or alternatively, in some examples, the stack 600 includes more than one channel 606 extending therethrough.

In the illustrated example of FIG. 6, the channel 606 of fluid coolant 608 serves as a first heatsink assembly 610 thermally coupled to a first hotspot 138 in the first semiconductor die 602 and a second heatsink assembly 612 thermally coupled to a second hotspot 138 in the second semiconductor die 604. As discussed above, in some examples, the hotspots 138 are thermally coupled to the respective heatsink assemblies 610, 612 (e.g., different portions of the channel 606) based on the elongate plates 146 of thermally conductive material 144 extending therebetween. In some examples, the thermally conductive material 144 is in direct contact with a wall of the channel 606 for direct thermal coupling with the channel 606 and/or direct thermal coupling with the fluid coolant 608 flowing through the channel 606. In other examples, the thermally conductive material 144 is spaced apart from the channel 606 but constructed to be in close proximity to the channel 606. More particularly, in some examples, as shown in FIG. 7, the thermally conductive material 144 includes a thermal ring 702 that at least partially surrounds the channel 606. In some examples, the ring 702 can be constructed similar to the ring(s) 148 adjacent the hotspots 138 as described above in connection with FIGS. 1-4. More particularly, FIG. 7 shows the thermally conductive material 144 in a single metal layer 704 on one side of a base semiconductor (e.g., silicon) substrate 614 of a particular die (e.g., the first or second semiconductor dies 108, 110 of FIG. 1, the first or second semiconductor dies 602, 604 of FIG. 6, etc.).

In some examples, the ring 702 surrounding the channel 606 is one of multiple rings defined in different metal layers to collectively define a cage (e.g., similar to the cage 408 shown in FIGS. 4 and/or 5) surrounding at least a portion of the channel 606 extending through the semiconductor die. For instance, FIG. 8 shows a cross-sectional view of a wall of an example thermal cage 802 viewed along the plane 706 identified in FIG. 7. As shown in the illustrated example, the wall of the cage 802 is defined by thermally conductive material 144 in the first metal layer 704 as well as other metal layers 708, 710, 712, 714, 716 on both sides (e.g., the frontside and backside) of the semiconductor substrate 614. Further, in this example, the different metal layers 708, 710, 712, 714, 716 (containing different rings 702) are thermally coupled by metal vias 718 extending through dielectric layers 720 (e.g., intermetal dielectric material) on either side of the semiconductor substrate 614. Further still, in some examples, the thermally conductive material 144 on either side of the semiconductor substrate 614 is thermally coupled by through silicon vias (TSVs) 722 extending through the semiconductor substrate.

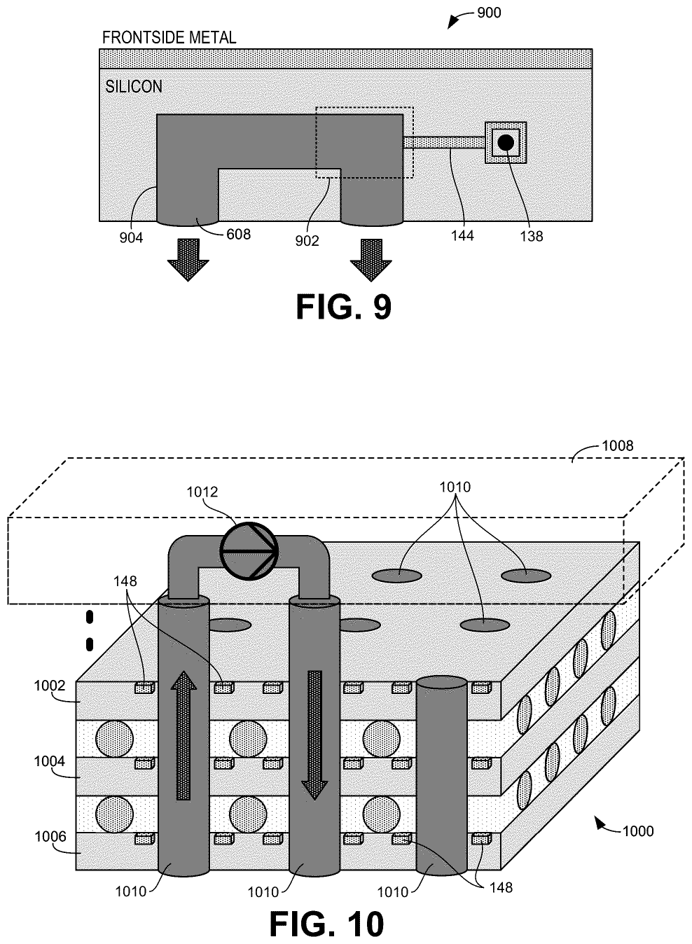

FIG. 9 illustrates another example semiconductor die 900 constructed in accordance with teachings disclosed herein. As with the example of FIGS. 6 and 7, the example semiconductor die 900 of FIG. 9 includes a channel 904 through which a fluid coolant 608 is to flow to serve as a heatsink assembly 902 that is thermally coupled to an associated hotspot 138 via thermally conductive material 144. However, unlike the example shown in FIGS. 6 and 7, the channel 904 does not extend all the way through the semiconductor die 900 in the illustrated example of FIG. 9. Rather, the channel 904 defines a U-shaped path for the coolant 608 to enter and leave the semiconductor die 900 from the same side (e.g., the backside of the die in this example). The example construction shown in FIG. 9 is suitable for 2.5 D integrated circuits in which the semiconductor die 900 is mounted to an interposer or other carrier wafer. In some such examples, the interposer or other carrier wafer includes corresponding channel(s) that fluidly couple with the channel 904 in the semiconductor die 900. In some examples, the interposer or other carrier wafer is a silicon-based substrate that includes a microelectromechanical system (MEMS) that implements a pump to force the fluid coolant 608 through the channel 904 of the semiconductor die 900.

A MEMS pump can also be used to pump the coolant 608 through channels extending through a 3D stack of dies (such as the 3D stack 600 of FIG. 6) as illustrated in FIG. 10. More particularly, FIG. 10 illustrates a 3D stack 1000 of multiple semiconductor dies 1002, 1004, 1006 coupled to an interposer or carrier wafer 1008. As shown in the illustrated example, multiple different channels 1010 extend through the die stack 1000 at different locations distributed across the stack. In this example, cross-sectional portions of rings 148 are shown on either side of the channels 1010 within each of the semiconductor dies 1002, 1004, 1006. In some examples, the rings 148 facilitate thermally coupling of the channels 1010 with hotspots in the respective semiconductor dies 1002, 1004, 1006 as discussed above. In some examples, at least some of the rings 148 are omitted in at least some of the dies 1002, 1004, 1006.

In some examples, different ones of the channels 1010 are fluidly coupled in series both upstream and downstream of a MEMS pump 1012 that serves to move the coolant 608 into and out of the stack 1000 of the semiconductor dies 1002, 1004, 1006. In some examples, the semiconductor die farthest away from the carrier wafer 1008 includes U-shaped channels (similar to the channel 904 of FIG. 9) to fluidly couple the channels 1010 at the ends opposite the carrier wafer 1008. In some examples, the carrier wafer 1008 includes multiple MEMS pumps 1012 to pump the coolant 608 through different ones of the channels 1010. In some such examples, the different MEMS pumps 1012 are connected to the same network of channels 1010. That is, in some examples, the different MEMS pumps 1012 are fluidly coupled together at different parts of a common cooling system. In other examples, different ones of the MEMS pumps 1012 and the associated channels 1010 are fluidly isolated from one another (e.g., they are part of separate cooling systems).

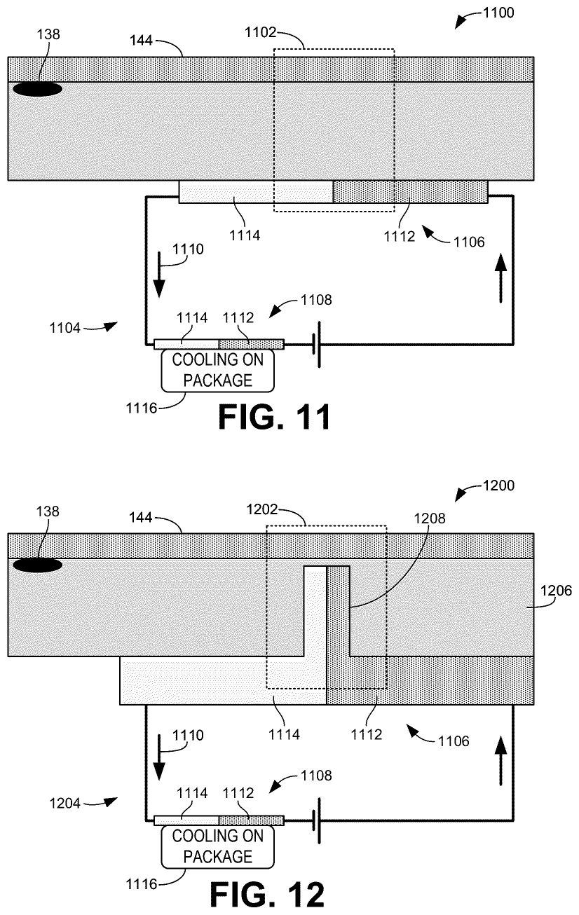

FIG. 11 illustrates another example semiconductor die 1100 constructed in accordance with teachings disclosed herein. In this example, the semiconductor die 1100 includes a heatsink assembly 1102 implemented based on a Peltier device 1104 that includes a first region 1106 that absorbs heat and a second region 1108 that generates heat based on a current 1110 passing through an associated circuit. More particularly, as shown in the illustrated example, each of the first and second regions 1106, 1108 of the Peltier device 1104 include a first metal 1112 physically coupled to a different second metal 1114 in series along the circuit. The connection of two different metals in series along a circuit is also known as a Peltier junction. Which of the two Peltier junctions (associated with each of the two regions 1106, 1108) absorbs heat and which generates heat is a function of the order in which the first and second metals are arranged relative to the direction of the current 1110 in the circuit. In this example, the direction of the current 1110 results in the first region 1106 absorbing heat, thereby enabling the adjacent area of the semiconductor die 1100 to be cooled to serve as a heatsink assembly 1102 that can draw heat away from a hotspot 138 that is transferred to the heatsink assembly 1102 by the thermally conductive material 144 extending therebetween. In some examples, the thermally conductive material 144 includes one or more rings 148 to at least partially surround so as to be thermally coupled with the hotspot 138 as discussed above. In the illustrated example of FIG. 11, the second region 1108 of the Peltier device 1104 is thermally coupled to a cooling source 1116 external to the semiconductor die 1100 (e.g., another die in a die stack, an underlying interposer and/or package substrate, an integrated heat spreader, etc.). As a result, the heat generated by the second region 1108 (corresponding to the heat absorbed by the first region 1106) is dissipated to a location away from the hotspot 138 to reduce (e.g., prevent) overheating of the semiconductor die 1100.

FIG. 12 illustrates another example semiconductor die 1200 constructed in accordance with teachings disclosed herein. In this example, the semiconductor die 1200 includes a heatsink assembly 1202 implemented based on another example Peltier device 1204. The example Peltier device 1204 of FIG. 12 is substantially the same as the example Peltier device 1104 of FIG. 11 except as otherwise noted or made clear from the context. As such, the same reference numbers used in FIG. 11 are used for the same or similar features shown in FIG. 12. Further, the foregoing description of such features applies similarly to the illustrated example of FIG. 12. The example Peltier device 1204 of FIG. 12 differs from the Peltier device 1104 of FIG. 11 in the construction of the Peltier junction in the first region 1106. More particularly, as shown in the illustrated example, rather than the first and second metals 1112, 1114 merely extending along a surface of the semiconductor die 1200, the junction extends into and across a majority of the thickness of the semiconductor substrate 1206 of the semiconductor die 1200. That is, in the illustrated example of FIG. 12, the first and second metals 1112, 1114 extend into a via and/or trench 1208 at an interface of the two metals 1112, 1114. As shown, the trench 1208 extends into the semiconductor substrate 1206 towards the thermally conductive material 144 on the opposite side of the semiconductor substrate 1206, thereby reducing the distance between the metal on either side and increasing the heat transfer between the metal on either side.

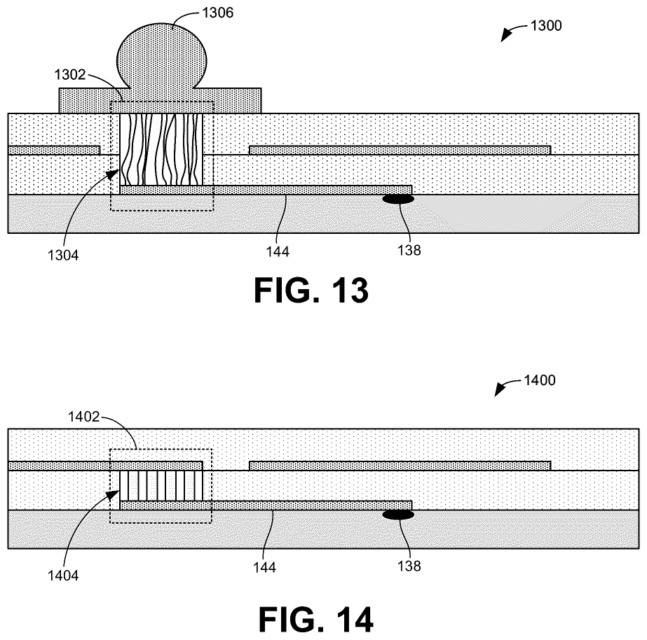

FIG. 13 illustrates another example semiconductor die 1300 constructed in accordance with teachings disclosed herein. In this example, the semiconductor die 1300 includes a heatsink assembly 1302 implemented using a field or array of carbon nanotubes 1304. As with other examples disclosed herein, the heatsink assembly 1302 is thermally coupled with a disparately located hotspot 138 through thermally conductive material 144 extending therebetween. As discussed above, the thermally conductive material 144 can include the metal used for routing of electrical interconnects such as copper, which has a thermal conductivity of approximately 400 W/mK. By contrast, carbon nanotubes are known to have a significantly higher thermal conductivity (e.g., over 2800 W/mK and as high as approximately 6000 W/mK). As such, the example carbon nanotubes 1304 are able to serve as a heatsink assembly 1302 to efficiently draw away heat from the thermally conductive material 144 that is transferred from the hotspot 138. In this example, the heatsink assembly 1302 dissipates the heat away from the semiconductor die 1300 by passing the heat to one or more contacts 1306 (e.g., bumps corresponding to the first level interconnects 116 of FIG. 1) to then be transferred to an associated substrate (e.g., another die in a die stack, an underlying interposer and/or package substrate, an integrated heat spreader, etc.).

FIG. 14 illustrates another example semiconductor die 1400 constructed in accordance with teachings disclosed herein. In this example, the semiconductor die 1400 includes a heatsink assembly 1402 implemented using one or more phase-change material (PMC) 1404 (e.g., a polymer-based recyclable solid/solid PMC). As with other examples disclosed herein, the heatsink assembly 1402 is thermally coupled with a disparately located hotspot 138 through thermally conductive material 144 extending therebetween. In some examples, unlike other heatsink assemblies disclosed herein, the example heatsink assembly 1402 does not need to be thermally coupled to an external component to which heat from the hotspot 138 is dissipated because the heat is not directly transferred external to the semiconductor die 1400. Instead, the heat absorbed by the phase-change material 1404 is stored in the material as a result of the material undergoing a phase change. In some examples, the phase change includes a change between a solid state and a liquid state. In some examples, the phase change includes a change from one crystalline structure to a different crystalline structure.

In some examples, the phase-change material 1404 may reverse the phase change process during which the stored heat is dissipated and dispersed into the area of the semiconductor die 1400 surrounding the heatsink assembly 1402. Such a heatsink assembly 1402 would not be able to absorb heat from the hotspot 138 after having already gone through the phase change. Accordingly, in some examples, the heatsink assembly 1402 of FIG. 14 is limited for use in conjunction with hotspots 138 that are known to be transient and active for only brief periods of time (e.g., less than 10 microseconds) such as overclocking or overdrive situations. That is, the example heatsink assembly 1402 may not dissipate heat away from the semiconductor die 1400, but it still serves as a temporary thermal buffer to mitigate against brief temperature peaks.

Although it may not be necessary to thermally couple the heatsink assembly 1402 to an area external to the semiconductor die 1400 because the hotspot 138 will no longer be hot by the time the phase-change material 1404 reverses its phase and releases the latent heat stored therein, in some examples, the heatsink assembly 1402 is nevertheless thermally coupled to components that direct the released heat towards an area external to the semiconductor die 1400 (e.g., another die in a die stack, an underlying interposer and/or package substrate, an integrated heat spreader, etc.).

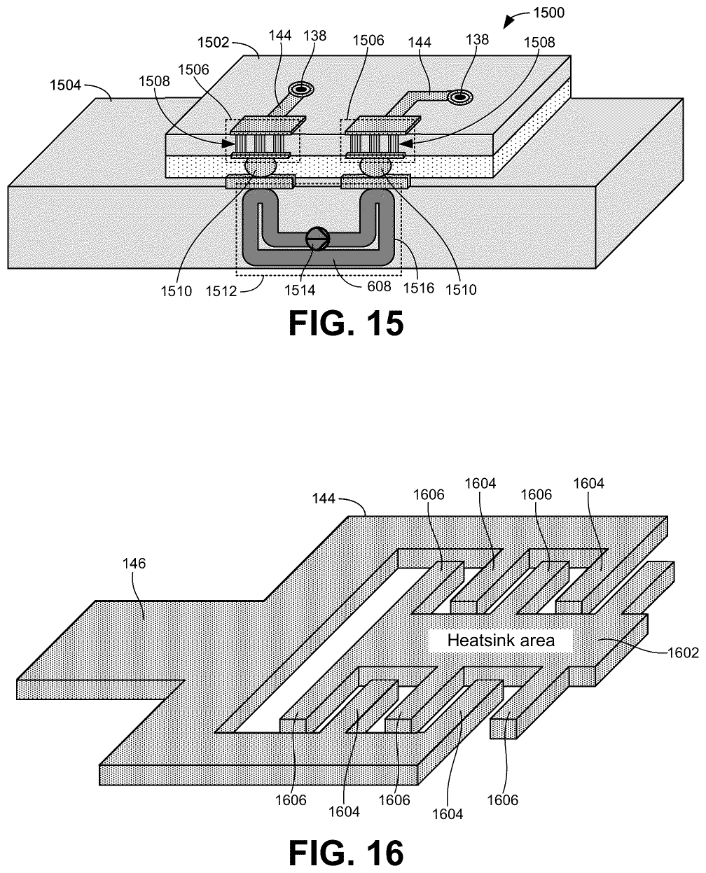

In some examples, a given semiconductor die can include different ones of the different types of example heatsink assemblies 140, 610, 612, 902, 1102, 1202, 1302, 1402 depending on the space constraints and cooling requirements of the various hotspot(s) 138 in the semiconductor die. In other words, the different example heatsink assemblies 140, 610, 612, 902, 1102, 1202, 1302, 1402 disclosed herein are not mutually exclusive but can be implemented together in any suitable combination. Furthermore, in some examples, multiple different heatsink assemblies can be used to cool the same hotspots 138 and/or can be used in combination as part of a single cooling system. For instance, in some examples, the carbon nanotubes 1304 of FIG. 13 can be used as a first stage heatsink assembly that facilitates the transfer of heat towards a channel of fluid coolant according similar to the examples shown in FIGS. 6-10. FIG. 15 is a specific example implementation of such a cooling system within an example IC package 1500 constructed in accordance with teachings disclosed herein.

As shown in the illustrated example of FIG. 15, a semiconductor die 1502 is mounted to an interposer 1504. In this example, the semiconductor die 1502 includes two hotspots 138 thermally coupled to respective heatsink assemblies 1506 by thermally conductive material 144. Both heatsink assemblies 1506 include arrays of carbon nanotubes 1508 that thermally couple the thermally conductive material 144 with micro-bumps 1510 that connect the semiconductor die 1502 to the interposer 1504. Further, in this example, the interposer 1504 includes a second heatsink assembly 1512 implemented with a MEMS pump 1514 to cause a coolant 608 to flow through a channel 1516 that passes in proximity to the micro-bumps 1510 to draw away heat from the micro-bumps 1510. In this manner, heat produced by the hotspots 138 is transferred towards the first heatsink assemblies 1506 and onward to the second heatsink assembly 1512 to dissipate the heat.

Other arrangements are possible. For instance, in some examples, the channel 1516 (or at least a portion thereof) is implemented internally within the semiconductor die 1502. Further, in some examples, the channel 1516 (and/or any of the channels 606, 904, 1010 of FIGS. 6-10) can be in fluid communication with an external fluid cooling system (e.g., external to the associated IC package). In some such examples, the MEMS pump 1012, 1514 may be omitted with the coolant 608 being pumped through the channels 606, 904, 1010, 1516 by the external cooling system.

As discussed above, in some examples, the thermally conductive material 144 extending between a hotspot 138 and a heatsink assembly 140, 610, 612, 902, 1102, 1202, 1302, 1402, 1506 is in direct contact with the heatsink assembly 140, 610, 612, 902, 1102, 1202, 1302, 1402, 1506. However, in some instances, a direct connection may be unsuitable because the thermally conductive material 144 needs to remain electrically isolated from the heatsink assembly 140, 610, 612, 902, 1102, 1202, 1302, 1402, 1506. Accordingly, in some examples, the thermally conductive material 144 at least partially surrounds the heatsink assembly 140, 610, 612, 902, 1102, 1202, 1302, 1402, 1506 (e.g., as shown in FIG. 7). FIG. 16 illustrates another arrangement to facilitate heat transfer between the thermally conductive material 144 and a heatsink area 1602 corresponding to any given type of heatsink assembly 140, 610, 612, 902, 1102, 1202, 1302, 1402, 1506. Specifically, in this example, the thermally conductive material 144 includes a first set of fingers 1604 that are spaced apart and interleaved with a second set of fingers 1606 extending from the heatsink area 1602. In some examples, the interweaved fingers 1604, 1606 are used in multiple different layers as part of a thermal cage similar to the cage 802 described above in connection with FIG. 8. In some examples, similar finger-like structures are used in conjunction with the rings 148 at the end of the thermally conductive material 144 proximate to a hotspot 138. In some such examples, such fingers are interleaved between electric routing that is electrically coupled to the transistors that are the source of the heat generated for the hotspot 138.

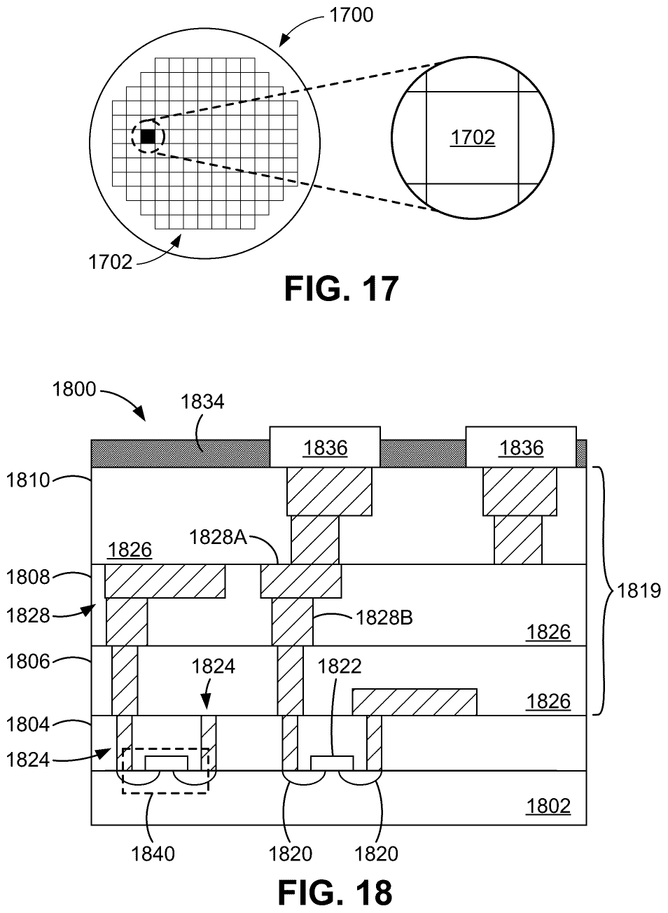

The example IC packages 100, 1500 and associated semiconductor dies 108, 110, 602, 604, 900, 1002, 1100, 1200, 1300, 1400, 1502 disclosed herein may be included in any suitable electronic component. FIGS. 17-20 illustrate various examples of apparatus that may include or be included in the IC packages 100, 1500 and associated semiconductor dies 108, 110, 602, 604, 900, 1002, 1100, 1200, 1300, 1400, 1502 disclosed herein.

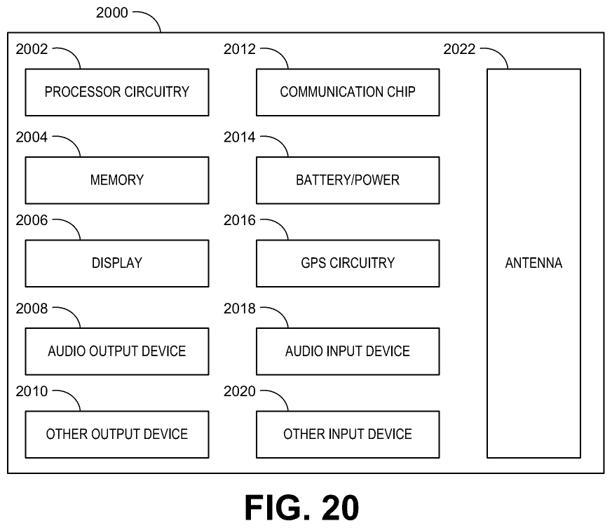

FIG. 17 is a top view of a wafer 1700 and dies 1702 that may include one or more example cooling systems in accordance with any of the examples disclosed herein. The wafer 1700 includes semiconductor material and one or more dies 1702 having circuitry. Each of the dies 1702 may be a repeating unit of a semiconductor product. After the fabrication of the semiconductor product is complete, the wafer 1700 may undergo a singulation process in which the dies 1702 are separated from one another to provide discrete “chips.” The die 1702 includes one or more transistors (e.g., some of the transistors 1840 of FIG. 18, discussed below), supporting circuitry to route electrical signals to the transistors, passive components (e.g., traces, resistors, capacitors, inductors, and/or other circuitry), and/or any other components. In some examples, the die 1702 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 1702. For example, a memory array of multiple memory circuits may be formed on a same die 1702 as programmable circuitry (e.g., the processor circuitry 2002 of FIG. 20) and/or other logic circuitry. Such memory may store information for use by the programmable circuitry. The example IC packages 100, 1500 and/or the associated semiconductor dies 108, 110, 602, 604, 900, 1002, 1100, 1200, 1300, 1400, 1502 disclosed herein may be manufactured using a die-to-wafer assembly technique in which some dies are attached to a wafer 1700 that includes others of the dies, and the wafer 1700 is subsequently singulated.

FIG. 18 is a cross-sectional side view of an IC device 1800 that may be included in the example IC packages 100, 1500 and/or the associated semiconductor dies 108, 110, 602, 604, 900, 1002, 1100, 1200, 1300, 1400, 1502. One or more of the IC devices 1800 may be included in one or more dies 1702 (FIG. 17). The IC device 1800 may be formed on a die substrate 1802 (e.g., the wafer 1700 of FIG. 17) and may be included in a die (e.g., the die 1702 of FIG. 17). The die substrate 1802 may be a semiconductor substrate including semiconductor materials including, for example, n-type or p-type materials systems (or a combination of both). The die substrate 1802 may include, for example, a crystalline substrate formed using a bulk silicon or a silicon-on-insulator (SOI) substructure. In some examples, the die substrate 1802 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1802. Although a few examples of materials from which the die substrate 1802 may be formed are described here, any material that may serve as a foundation for an IC device 1800 may be used. The die substrate 1802 may be part of a singulated die (e.g., the dies 1702 of FIG. 17) or a wafer (e.g., the wafer 1700 of FIG. 17).

The IC device 1800 may include one or more device layers 1804 disposed on and/or above the die substrate 1802. The device layer 1804 may include features of one or more transistors 1840 (e.g., metal oxide semiconductor field-effect transistors (MOSFETs)) formed on the die substrate 1802. The device layer 1804 may include, for example, one or more source and/or drain (S/D) regions 1820, a gate 1822 to control current flow between the S/D regions 1820, and one or more S/D contacts 1824 to route electrical signals to/from the S/D regions 1820. The transistors 1840 may include additional features not depicted for the sake of clarity, such as device isolation regions, gate contacts, and the like. The transistors 1840 are not limited to the type and configuration depicted in FIG. 18 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1840 may include a gate 1822 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1840 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 1840 along the source-channel-drain direction, the gate electrode may include a U-shaped structure that includes a bottom portion substantially parallel to the surface of the die substrate 1802 and two sidewall portions that are substantially perpendicular to the top surface of the die substrate 1802. In other examples, at least one of the metal layers that form the gate electrode may be a planar layer that is substantially parallel to the top surface of the die substrate 1802 and does not include sidewall portions substantially perpendicular to the top surface of the die substrate 1802. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 1820 may be formed within the die substrate 1802 adjacent to the gate 1822 of corresponding transistor(s) 1840. The S/D regions 1820 may be formed using an implantation/diffusion process or an etching/deposition process, for example. In the former process, dopants such as boron, aluminum, antimony, phosphorous, or arsenic may be ion-implanted into the die substrate 1802 to form the S/D regions 1820. An annealing process that activates the dopants and causes them to diffuse farther into the die substrate 1802 may follow the ion-implantation process. In the latter process, the die substrate 1802 may first be etched to form recesses at the locations of the S/D regions 1820. An epitaxial deposition process may then be carried out to fill the recesses with material that is used to fabricate the S/D regions 1820. In some implementations, the S/D regions 1820 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1820 may be formed using one or more alternate semiconductor materials such as germanium or a group III-V material or alloy. In further examples, one or more layers of metal and/or metal alloys may be used to form the S/D regions 1820.

Electrical signals, such as power and/or input/output (I/O) signals, may be routed to and/or from the devices (e.g., transistors 1840) of the device layer 1804 through one or more interconnect layers disposed on the device layer 1804 (illustrated in FIG. 18 as interconnect layers 1806-1810). For example, electrically conductive features of the device layer 1804 (e.g., the gate 1822 and the S/D contacts 1824) may be electrically coupled with the interconnect structures 1828 of the interconnect layers 1806-1810. The one or more interconnect layers 1806-1810 may form a metallization stack (also referred to as an “ILD stack”) 1819 of the IC device 1800.

The interconnect structures 1828 may be arranged within the interconnect layers 1806-1810 to route electrical signals according to a wide variety of designs (in particular, the arrangement is not limited to the particular configuration of interconnect structures 1828 depicted in FIG. 18). Although a particular number of interconnect layers 1806-1810 is depicted in FIG. 18, examples of the present disclosure include IC devices having more or fewer interconnect layers than depicted.

In some examples, the interconnect structures 1828 may include lines 1828a and/or vias 1828b filled with an electrically conductive material such as a metal. The lines 1828a may be arranged to route electrical signals in a direction of a plane that is substantially parallel with a surface of the die substrate 1802 upon which the device layer 1804 is formed. For example, the lines 1828a may route electrical signals in a direction in and/or out of the page from the perspective of FIG. 18. The vias 1828b may be arranged to route electrical signals in a direction of a plane that is substantially perpendicular to the surface of the die substrate 1802 upon which the device layer 1804 is formed. In some examples, the vias 1828b may electrically couple lines 1828a of different interconnect layers 1806-1810 together.

The interconnect layers 1806-1810 may include a dielectric material 1826 disposed between the interconnect structures 1828, as shown in FIG. 18. In some examples, the dielectric material 1826 disposed between the interconnect structures 1828 in different ones of the interconnect layers 1806-1810 may have different compositions; in other examples, the composition of the dielectric material 1826 between different interconnect layers 1806-1810 may be the same.

A first interconnect layer 1806 (referred to as Metal 1 or “M1”) may be formed directly on the device layer 1804. In some examples, the first interconnect layer 1806 may include lines 1828a and/or vias 1828b, as shown. The lines 1828a of the first interconnect layer 1806 may be coupled with contacts (e.g., the S/D contacts 1824) of the device layer 1804.

A second interconnect layer 1808 (referred to as Metal 2 or “M2”) may be formed directly on the first interconnect layer 1806. In some examples, the second interconnect layer 1808 may include vias 1828b to couple the lines 1828a of the second interconnect layer 1808 with the lines 1828a of the first interconnect layer 1806. Although the lines 1828a and the vias 1828b are structurally delineated with a line within each interconnect layer (e.g., within the second interconnect layer 1808) for the sake of clarity, the lines 1828a and the vias 1828b may be structurally and/or materially contiguous (e.g., simultaneously filled during a dual-damascene process) in some examples.

A third interconnect layer 1810 (referred to as Metal 3 or “M3”) (and additional interconnect layers, as desired) may be formed in succession on the second interconnect layer 1808 according to similar techniques and/or configurations described in connection with the second interconnect layer 1808 or the first interconnect layer 1806. In some examples, the interconnect layers that are “higher up” in the metallization stack 1819 in the IC device 1800 (i.e., further away from the device layer 1804) may be thicker.

The IC device 1800 may include a solder resist material 1834 (e.g., polyimide or similar material) and one or more conductive contacts 1836 formed on the interconnect layers 1806-1810. In FIG. 18, the conductive contacts 1836 are illustrated as taking the form of bond pads. The conductive contacts 1836 may be electrically coupled with the interconnect structures 1828 and configured to route the electrical signals of the transistor(s) 1840 to other external devices. For example, solder bonds may be formed on the one or more conductive contacts 1836 to mechanically and/or electrically couple a chip including the IC device 1800 with another component (e.g., a circuit board). The IC device 1800 may include additional or alternate structures to route the electrical signals from the interconnect layers 1806-1810; for example, the conductive contacts 1836 may include other analogous features (e.g., posts) that route the electrical signals to external components.

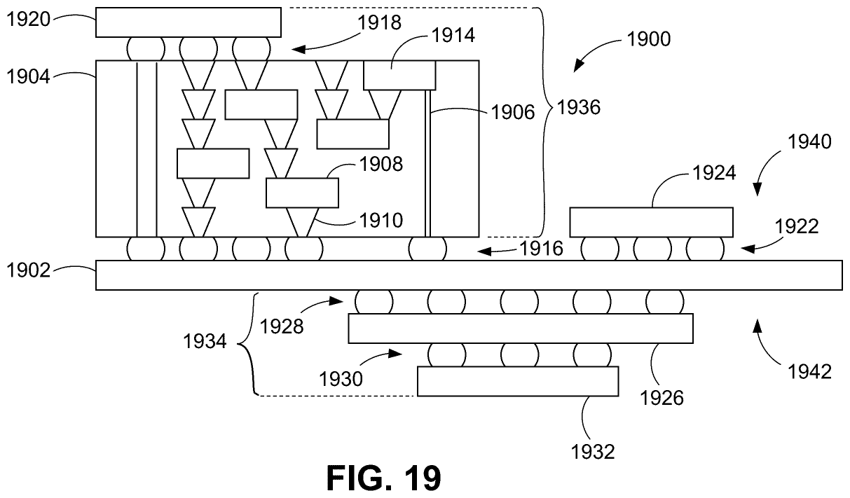

FIG. 19 is a cross-sectional side view of an IC device assembly 1900 that may include the example IC packages 100, 1500 and/or the associated semiconductor dies 108, 110, 602, 604, 900, 1002, 1100, 1200, 1300, 1400, 1502 disclosed herein. In some examples, the IC device assembly corresponds to one of the example IC packages 100, 1500 disclosed herein. The IC device assembly 1900 includes a number of components disposed on a circuit board 1902 (which may be, for example, a motherboard). The IC device assembly 1900 includes components disposed on a first face 1940 of the circuit board 1902 and an opposing second face 1942 of the circuit board 1902; generally, components may be disposed on one or both faces 1940 and 1942. Any of the IC packages discussed below with reference to the IC device assembly 1900 may take the form of the example IC package, 100, 1500 of FIGS. 1 and/or 15.

In some examples, the circuit board 1902 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1902. In other examples, the circuit board 1902 may be a non-PCB substrate.

The IC device assembly 1900 illustrated in FIG. 19 includes a package-on-interposer structure 1936 coupled to the first face 1940 of the circuit board 1902 by coupling components 1916. The coupling components 1916 may electrically and mechanically couple the package-on-interposer structure 1936 to the circuit board 1902, and may include solder balls (as shown in FIG. 19), male and female portions of a socket, an adhesive, an underfill material, and/or any other suitable electrical and/or mechanical coupling structure.

The package-on-interposer structure 1936 may include an IC package 1920 coupled to an interposer 1904 by coupling components 1918. The coupling components 1918 may take any suitable form for the application, such as the forms discussed above with reference to the coupling components 1916. Although a single IC package 1920 is shown in FIG. 19, multiple IC packages may be coupled to the interposer 1904; indeed, additional interposers may be coupled to the interposer 1904. The interposer 1904 may provide an intervening substrate used to bridge the circuit board 1902 and the IC package 1920. The IC package 1920 may be or include, for example, a die (the die 1702 of FIG. 17), an IC device (e.g., the IC device 1800 of FIG. 18), or any other suitable component. Generally, the interposer 1904 may spread a connection to a wider pitch or reroute a connection to a different connection. For example, the interposer 1904 may couple the IC package 1920 (e.g., a die) to a set of BGA conductive contacts of the coupling components 1916 for coupling to the circuit board 1902. In the example illustrated in FIG. 19, the IC package 1920 and the circuit board 1902 are attached to opposing sides of the interposer 1904; in other examples, the IC package 1920 and the circuit board 1902 may be attached to a same side of the interposer 1904. In some examples, three or more components may be interconnected by way of the interposer 1904.

In some examples, the interposer 1904 may be formed as a PCB, including multiple metal layers separated from one another by layers of dielectric material and interconnected by electrically conductive vias. In some examples, the interposer 1904 may be formed of an epoxy resin, a fiberglass-reinforced epoxy resin, an epoxy resin with inorganic fillers, a ceramic material, or a polymer material such as polyimide. In some examples, the interposer 1904 may be formed of alternate rigid or flexible materials that may include the same materials described above for use in a semiconductor substrate, such as silicon, germanium, and other group III-V and group IV materials. The interposer 1904 may include metal interconnects 1908 and vias 1910, including but not limited to through-silicon vias (TSVs) 1906. The interposer 1904 may further include embedded devices 1914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1904. The package-on-interposer structure 1936 may take the form of any of the package-on-interposer structures known in the art.

The IC device assembly 1900 may include an IC package 1924 coupled to the first face 1940 of the circuit board 1902 by coupling components 1922. The coupling components 1922 may take the form of any of the examples discussed above with reference to the coupling components 1916, and the IC package 1924 may take the form of any of the examples discussed above with reference to the IC package 1920.

The IC device assembly 1900 illustrated in FIG. 19 includes a package-on-package structure 1934 coupled to the second face 1942 of the circuit board 1902 by coupling components 1928. The package-on-package structure 1934 may include a first IC package 1926 and a second IC package 1932 coupled together by coupling components 1930 such that the first IC package 1926 is disposed between the circuit board 1902 and the second IC package 1932. The coupling components 1928, 1930 may take the form of any of the examples of the coupling components 1916 discussed above, and the IC packages 1926, 1932 may take the form of any of the examples of the IC package 1920 discussed above. The package-on-package structure 1934 may be configured in accordance with any of the package-on-package structures known in the art.

FIG. 20 is a block diagram of an example electrical device 2000 that may include one or more of the example IC packages 100, 1500 and/or the associated semiconductor dies 108, 110, 602, 604, 900, 1002, 1100, 1200, 1300, 1400, 1502. For example, any suitable ones of the components of the electrical device 2000 may include one or more of the device assemblies 1900, IC devices 1800, or dies 1702 disclosed herein, and may be arranged in the example IC packages 100, 1500 and/or the associated semiconductor dies 108, 110, 602, 604, 900, 1002, 1100, 1200, 1300, 1400, 1502. A number of components are illustrated in FIG. 20 as included in the electrical device 2000, but any one or more of these components may be omitted or duplicated, as suitable for the application. In some examples, some or all of the components included in the electrical device 2000 may be attached to one or more motherboards. In some examples, some or all of these components are fabricated onto a single system-on-a-chip (SoC) die.

Additionally, in various examples, the electrical device 2000 may not include one or more of the components illustrated in FIG. 20, but the electrical device 2000 may include interface circuitry for coupling to the one or more components. For example, the electrical device 2000 may not include a display 2006, but may include display interface circuitry (e.g., a connector and driver circuitry) to which a display 2006 may be coupled. In another set of examples, the electrical device 2000 may not include an audio input device 2018 (e.g., microphone) or an audio output device 2008 (e.g., a speaker, a headset, earbuds, etc.), but may include audio input or output device interface circuitry (e.g., connectors and supporting circuitry) to which an audio input device 2018 or audio output device 2008 may be coupled.

The electrical device 2000 may include programmable circuitry 2002 (e.g., one or more processing devices). The programmable circuitry 2002 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 2000 may include a memory 2004, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 2004 may include memory that shares a die with the programmable circuitry 2002. This memory may be used as cache memory and may include embedded dynamic random access memory (eDRAM) or spin transfer torque magnetic random access memory (STT-MRAM).

In some examples, the electrical device 2000 may include a communication chip 2012 (e.g., one or more communication chips). For example, the communication chip 2012 may be configured for managing wireless communications for the transfer of data to and from the electrical device 2000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 2012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2012 may operate in accordance with other wireless protocols in other examples. The electrical device 2000 may include an antenna 2022 to facilitate wireless communications and/or to receive other wireless communications (such as AM or FM radio transmissions).

In some examples, the communication chip 2012 may manage wired communications, such as electrical, optical, or any other suitable communication protocols (e.g., the Ethernet). As noted above, the communication chip 2012 may include multiple communication chips. For instance, a first communication chip 2012 may be dedicated to shorter-range wireless communications such as Wi-Fi or Bluetooth, and a second communication chip 2012 may be dedicated to longer-range wireless communications such as global positioning system (GPS), EDGE, GPRS, CDMA, WiMAX, LTE, EV-DO, or others. In some examples, a first communication chip 2012 may be dedicated to wireless communications, and a second communication chip 2012 may be dedicated to wired communications.

The electrical device 2000 may include battery/power circuitry 2014. The battery/power circuitry 2014 may include one or more energy storage devices (e.g., batteries or capacitors) and/or circuitry for coupling components of the electrical device 2000 to an energy source separate from the electrical device 2000 (e.g., AC line power).

The electrical device 2000 may include a display 2006 (or corresponding interface circuitry, as discussed above). The display 2006 may include any visual indicators, such as a heads-up display, a computer monitor, a projector, a touchscreen display, a liquid crystal display (LCD), a light-emitting diode display, or a flat panel display.

The electrical device 2000 may include an audio output device 2008 (or corresponding interface circuitry, as discussed above). The audio output device 2008 may include any device that generates an audible indicator, such as speakers, headsets, or earbuds.

The electrical device 2000 may include an audio input device 2018 (or corresponding interface circuitry, as discussed above). The audio input device 2018 may include any device that generates a signal representative of a sound, such as microphones, microphone arrays, or digital instruments (e.g., instruments having a musical instrument digital interface (MIDI) output).

The electrical device 2000 may include GPS circuitry 2016. The GPS circuitry 2016 may be in communication with a satellite-based system and may receive a location of the electrical device 2000, as known in the art.

The electrical device 2000 may include any other output device 2010 (or corresponding interface circuitry, as discussed above). Examples of the other output device 2010 may include an audio codec, a video codec, a printer, a wired or wireless transmitter for providing information to other devices, or an additional storage device.

The electrical device 2000 may include any other input device 2020 (or corresponding interface circuitry, as discussed above). Examples of the other input device 2020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 2000 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 2000 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a

semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that provide cooling systems directly within a semiconductor die to draw heat away from hotspots and/or other heat generating components in the semiconductor die, thereby reducing (e.g., avoiding) the occurrence of large temperature peaks and/or large temperature gradients across the die that would otherwise result in reliability issues, reduced performance, and/or device failure based on, for example, electromigration, active loss, and/or leakage currents. Disclosed cooling systems include a heatsink assembly that absorb or draw away the heat produced by a heat generating component (e.g., a hotspot). Such heatsink assemblies can be active (e.g., based on a flowing fluid coolant or the Peltier effect produced by a current applied across a bimetal material) or passive (e.g., based on highly thermally conductive material such as carbon nanotubes). Additionally or alternatively, a phase-change material can be used for temporal buffering of heat dissipation to mitigate against brief temperature peaks. In some examples, the heatsink assemblies can be placed at any suitable location relative to a heat generating component for greater circuit design flexibility. In some disclosed examples, the distance between the heatsink assembly is spanned by a thermally conductive material to provide thermal coupling between a heat generating component and a heatsink assembly. In some examples, the thermally conductive material includes rings and/or cages that at least partially surround (e.g., are adjacent and proximate to) the heat generating component and/or the heatsink assembly to improve the efficiency of heat transfer.

Further examples and combinations thereof include the following:

Example 1 includes an apparatus comprising a heat generating component associated with a first location in a semiconductor die, a heatsink assembly at a second location in the semiconductor die, the first location spaced apart from the second location, and a thermally conductive material to thermally couple the heat generating component and the heatsink assembly.

Example 2 includes the apparatus of example 1, wherein the thermally conductive material defines a ring to at least partially surround an area associated with the heat generating component.

Example 3 includes the apparatus of any one or more of examples 1 or 2, wherein the heatsink assembly includes a first set of thermally conductive fingers within a first metal layer in the semiconductor die, and the thermally conductive material defines a second set of thermally conductive fingers within the first metal layer, the second set of thermally conductive fingers interleaved with the first set of thermally conductive fingers.

Example 4 includes the apparatus of any one or more of examples 1-3, wherein the thermally conductive material is electrically isolated from the heat generating component.

Example 5 includes the apparatus of any one or more of examples 1-4, wherein the heatsink assembly defines a channel through which a fluid coolant is to flow.

Example 6 includes the apparatus of any one or more examples 1-5, wherein the semiconductor die is a first semiconductor die, and including a second semiconductor die stacked on the first semiconductor die, the channel extending through both the first semiconductor die and the second semiconductor die.

Example 7 includes the apparatus of any one or more of examples 1-6, including a substrate to support the semiconductor die, the substrate including a microelectromechanical systems (MEMS) pump operatively coupled to the channel to force the fluid coolant through the channel.

Example 8 includes the apparatus of any one or more of examples 1-7, wherein the thermally conductive material extends along a first metal layer within the semiconductor die, the channel extends in a direction transverse to the first metal layer, and the thermally conductive material at least partially surrounds the channel in a plane associated with the first metal layer.

Example 9 includes the apparatus of any one or more of examples 1-8, wherein a portion of the thermally conductive material is defined in a second metal layer within the semiconductor die that is different from the first metal layer, the thermally conductive material in the first and second metal layers thermally coupled by a metal via extending therebetween.

Example 10 includes the apparatus of any one of examples 1-9, wherein the heatsink assembly includes a Peltier junction.

Example 11 includes the apparatus of any one or more of examples 1-10, wherein the Peltier junction is on a backside of the semiconductor die and the thermally conductive material is on a frontside of the semiconductor die, the semiconductor die including a semiconductor substrate between the thermally conductive material and the Peltier junction.

Example 12 includes the apparatus of any one or more of examples 1-11, wherein the Peltier junction includes a first metal and a second metal different from the first metal, the first and second metals side-by-side along a surface of the semiconductor substrate, portions of the first and second metals at an interface between the first and second metals to extend into the semiconductor substrate towards the thermally conductive material.

Example 13 includes the apparatus of any one or more of examples 1-12, wherein the heatsink assembly includes a field of carbon nanotubes coupled to a contact on an external surface of the semiconductor die

Example 14 includes the apparatus of any one or more of examples 1-13, wherein the heatsink assembly includes a phase-change material.

Example 15 includes the apparatus of any one or more of examples 1-14, wherein the thermally conductive material includes graphene.

Example 16 includes an apparatus comprising a thermal guard ring to at least partially surround an area in a semiconductor die associated with a hotspot, a heatsink in the semiconductor die, the heatsink spaced apart from the hotspot, and a thermal conductor that extends between the thermal guard ring and the heatsink.

Example 17 includes the apparatus of example 16, wherein the thermal conductor is in direct contact with the heatsink.

Example 18 includes an apparatus comprising a semiconductor chip including a first area associated with a hotspot, a heatsink assembly within the semiconductor chip, the heatsink assembly spaced apart from the first area of the semiconductor chip, and a thermally conductive material to conduct heat from the hotspot toward the heatsink assembly.

Example 19 includes the apparatus of example 18, wherein the thermally conductive material includes an end plate proximate the hotspot and distal to the heatsink assembly, the end plate to at least partially surround the hotspot.

Example 20 includes the apparatus of any one or more of examples 18-19, wherein the end plate is a first end plate in a first metal layer within the semiconductor chip, and including a second end plate in a second metal layer different from the first metal layer, the first and second end plates defining portions of a cage that at least partially surrounds the hotspot.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a heat generating component associated with a first location in a semiconductor die;
a heatsink assembly at a second location in the semiconductor die, the first location spaced apart from the second location; and
a thermally conductive material to thermally couple the heat generating component and the heatsink assembly.

2. The apparatus of claim 1, wherein the thermally conductive material defines a ring to at least partially surround an area associated with the heat generating component.

3. The apparatus of claim 1, wherein the heatsink assembly includes a first set of thermally conductive fingers within a first metal layer in the semiconductor die, and the thermally conductive material defines a second set of thermally conductive fingers within the first metal layer, the second set of thermally conductive fingers interleaved with the first set of thermally conductive fingers.

4. The apparatus of claim 1, wherein the thermally conductive material is electrically isolated from the heat generating component.

5. The apparatus of claim 1, wherein the heatsink assembly defines a channel through which a fluid coolant is to flow.

6. The apparatus of claim 5, wherein the semiconductor die is a first semiconductor die, and including a second semiconductor die stacked on the first semiconductor die, the channel extending through both the first semiconductor die and the second semiconductor die.

7. The apparatus of claim 5, including a substrate to support the semiconductor die, the substrate including a microelectromechanical systems (MEMS) pump operatively coupled to the channel to force the fluid coolant through the channel.

8. The apparatus of claim 5, wherein the thermally conductive material extends along a first metal layer within the semiconductor die, the channel extends in a direction transverse to the first metal layer, and the thermally conductive material at least partially surrounds the channel in a plane associated with the first metal layer.

9. The apparatus of claim 8, wherein a portion of the thermally conductive material is defined in a second metal layer within the semiconductor die that is different from the first metal layer, the thermally conductive material in the first and second metal layers thermally coupled by a metal via extending therebetween.

10. The apparatus of claim 1, wherein the heatsink assembly includes a Peltier junction.

11. The apparatus of claim 10, wherein the Peltier junction is on a backside of the semiconductor die and the thermally conductive material is on a frontside of the semiconductor die, the semiconductor die including a semiconductor substrate between the thermally conductive material and the Peltier junction.

12. The apparatus of claim 11, wherein the Peltier junction includes a first metal and a second metal different from the first metal, the first and second metals side-by-side along a surface of the semiconductor substrate, portions of the first and second metals at an interface between the first and second metals to extend into the semiconductor substrate towards the thermally conductive material.

13. The apparatus of claim 1, wherein the heatsink assembly includes a field of carbon nanotubes coupled to a contact on an external surface of the semiconductor die.

14. The apparatus of claim 1, wherein the heatsink assembly includes a phase-change material.

15. The apparatus of claim 1, wherein the thermally conductive material includes graphene.

16. An apparatus comprising:
a thermal guard ring to at least partially surround an area in a semiconductor die associated with a hotspot;
a heatsink in the semiconductor die, the heatsink spaced apart from the hotspot; and
a thermal conductor that extends between the thermal guard ring and the heatsink.

17. The apparatus of claim 16, wherein the thermal conductor is in direct contact with the heatsink.

18. An apparatus comprising:
a semiconductor chip including a first area associated with a hotspot;
a heatsink assembly within the semiconductor chip, the heatsink assembly spaced apart from the first area of the semiconductor chip; and
a thermally conductive material to conduct heat from the hotspot toward the heatsink assembly.

19. The apparatus of claim 18, wherein the thermally conductive material includes an end plate proximate the hotspot and distal to the heatsink assembly, the end plate to at least partially surround the hotspot.

20. The apparatus of claim 19, wherein the end plate is a first end plate in a first metal layer within the semiconductor chip, and including a second end plate in a second metal layer different from the first metal layer, the first and second end plates defining portions of a cage that at least partially surrounds the hotspot.
